(19) United States
(12) Patent Application Publication
(10) Pub. No.: US 2010/0096717 A1
(43) Pub. Date: Apr. 22, 2010

(54) ELECTRONIC DEVICE AND PROCESS FOR MANUFACTURING ELECTRONIC DEVICE

(75) Inventors: Kenji UCHIDA, Kanagawa (JP); Koki HIRASAWA, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kawasaki-shi (JP)

(21) Appl. No.: 12/580,388

(22) Filed: Oct. 16, 2009

(30) Foreign Application Priority Data
Oct. 16, 2008 (JP) 2008-267547

(51) Int. Cl. H01L 23/02

(52) U.S. Cl. 257/434; 156/245; 156/272.2; 257/E23.18

(57) ABSTRACT

To reduce cracks in a functional unit of a semiconductor element in a process for manufacturing an electronic device, a frame member surrounds a functional unit and an optically-transparent layer is formed on a wafer. A resin layer is formed by injecting resin into a cavity of an encapsulating metallic mold while a molding surface of the encapsulating metallic mold segment contacts an upper surface of the frame member. After forming the resin layer, an optically-transparent layer is formed inside the frame member. The resin layer is formed by injecting resin while the frame member contacts the molding surface of the encapsulating metallic mold segment. Therefore, pressure applied in the encapsulation is exerted over the frame member around the functional unit. Further, the optically-transparent layer is formed after encapsulation. This avoids pressure applied to the functional unit from the contact of the encapsulating metallic mold segment with the optically-transparent layer.

This application is based on Japanese patent application No. 2008-267,547, the content of which is incorporated hereinto by reference.

### BACKGROUND

1. Technical Field

The present invention relates to an electronic device and a process for manufacturing an electronic device.

2. Background Art

Photo-sensitive elements employed in a photo-detector for a digital versatile disk (DVD) or in an imaging device for a digital camera are generally configured to be covered with a transparent encapsulation resin to guide an optical signal to a light conductor, while protecting the photo-sensitive element from externally-exerted stress. These photo-sensitive elements generally have configurations, in which photo-sensitive elements are individually arranged with a certain distance therebetween on a lead frame serving as a substrate, and the lead frame is encapsulated with a transparent resin to provide coverage.

As typical electronic devices for processing optical signals, for example, Japanese Patent Laid-Open No. 2000-173,947 discloses a plastic package including a transparent lens directly joined to a photo-sensitive unit or a photo-emitting unit of a photo device chip, and a mold section composed of an insulating mold resin material. The lens, which has been formed to have a lens-shape, is joined to a photo-sensitive unit via an anodic bonding, and then, a molding process is carried out with a mold resin material containing glass filler mixed at a certain rate.

Japanese Patent Laid-Open No. H03-11,757 (1991) also discloses a lead frame structure, in which a solid pickup element is adhered to a transparent member composed of a borosilicate glass and a transparent resin layer formed on one side of the borosilicate glass. It is also described that the lead frame structure is installed in a metallic mold, and is molded with an epoxy resin via a transfer molding process to form a molded resin.

Related technologies are also disclosed in Japanese Patent Laid-Open No. S62-257,757 (1987) and Japanese Patent Laid-Open No. S58-207,656 (1983).

In the technologies described in the above-described literatures, an encapsulating metallic mold is employed when the outer circumference of the transparent member is covered with an encapsulating resin, and the encapsulating resin is injected into the cavity of the encapsulating metallic mold. Consequently, a strong and close contact of the transparent member with the encapsulating metallic mold is required, in order to avoid a penetration of the encapsulating resin between the transparent member and the metallic mold. Therefore, a pressure generated by clamping the encapsulating metallic mold is exerted over the functional units of the semiconductor element through the transparent member, so that the functional unit of the semiconductor element may not bear the pressure. This may lead to a generation of a failure such as a generation of cracks or the like in the semiconductor element.

### SUMMARY

According to one aspect of the present invention, there is provided a process for manufacturing an electronic device, comprising: forming a resin film composed of a first resin over a wafer having a plurality of elements formed therein; patterning the resin film to form a frame member installed to surround the functional unit of the element; and forming a resin layer by injecting a second resin into a cavity of an encapsulating metallic mold while a molding surface of the encapsulating metallic mold is in contact with an upper surface of the frame member, the resin layer filling a periphery of the frame member, wherein the process includes, before or after the forming the resin layer, forming an optically-transparent layer in a space in the inside of the frame member.

In the process for manufacturing the electronic device, a frame member installed to surround the functional unit and the optically-transparent layer is formed over the wafer, and then the resin is injected into the cavity of the encapsulating metallic mold while the molding surface of the encapsulating metallic mold is in contact with the upper surface of the frame member to form the resin layer, which fills the periphery of the frame member, and before or after the forming the resin layer, the optically-transparent layer is formed in the space in the inside of the frame member. The resin layer is formed by injecting the encapsulating resin while the frame member is in contact with the molding surface of the encapsulating metallic mold. Therefore, a pressure applied in the encapsulation with the encapsulating metallic mold is exerted over the frame member around the functional unit. Further, the optically-transparent layer is formed after the encapsulation, or is located to be lower than the height of the frame member during the encapsulating process. Therefore, a transfer of the pressure applied in the encapsulation to the functional unit caused by the contact of the encapsulating metallic mold with the optically-transparent layer can be avoided. This allows reducing the pressure applied in the encapsulation caused by the contact of the encapsulating metallic mold with the functional unit. Therefore, a generation of a crack in the functional unit of the semiconductor element can be reduced.

According to the present invention, the electronic devices configured to be adopted for reducing a generation of a crack in the functional unit of the semiconductor element, as well as the processes for manufacturing the electronic device, are achieved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A is a perspective view, illustrating an electronic device in an embodiment, and FIG. 1B is a cross-sectional view along line A-A′ shown in FIG. 1A;

FIGS. 2A to 2D are cross-sectional views, illustrating a process for manufacturing an electronic device in an embodiment;

FIGS. 3A to 3C are cross-sectional views, illustrating the process for manufacturing the electronic device in an embodiment;

FIGS. 4A to 4C are cross-sectional views, illustrating the process for manufacturing the electronic device in an embodiment;

FIGS. 5A to 5C are cross-sectional views, illustrating the process for manufacturing the electronic device in an embodiment;

FIGS. 6A to 6C are cross-sectional views, illustrating a process for manufacturing an electronic device in an embodiment;

FIGS. 7A to 7C are cross-sectional views, illustrating the process for manufacturing the electronic device in an embodiment;

FIGS. 8A to 8C are cross-sectional views, illustrating a process for manufacturing an electronic device in an embodiment;

FIGS. 9A to 9C are cross-sectional views, illustrating the process for manufacturing the electronic device in an embodiment;

FIGS. 10A to 10C are cross-sectional views, illustrating the process for manufacturing the electronic device in an embodiment;

FIGS. 11A to 11F are cross-sectional views, illustrating a process for manufacturing an electronic device in a modified embodiment;

FIGS. 12A and 12B are cross-sectional views, illustrating a process for manufacturing an electronic device in a modified embodiment; and

FIG. 13 is a cross-sectional view, illustrating the process for manufacturing the electronic device in a modified embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations for electronic devices and processes for manufacturing thereof according to the present invention will be described in detail as follows in reference to the annexed figures. In all figures, an identical numeral is assigned to an element commonly appeared in the figures, and the detailed description thereof will not be repeated.

### First Embodiment

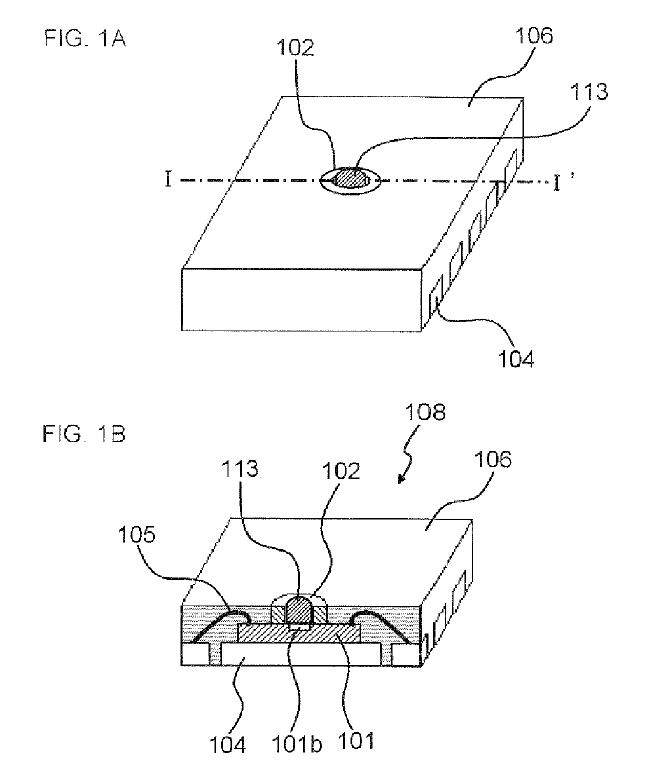

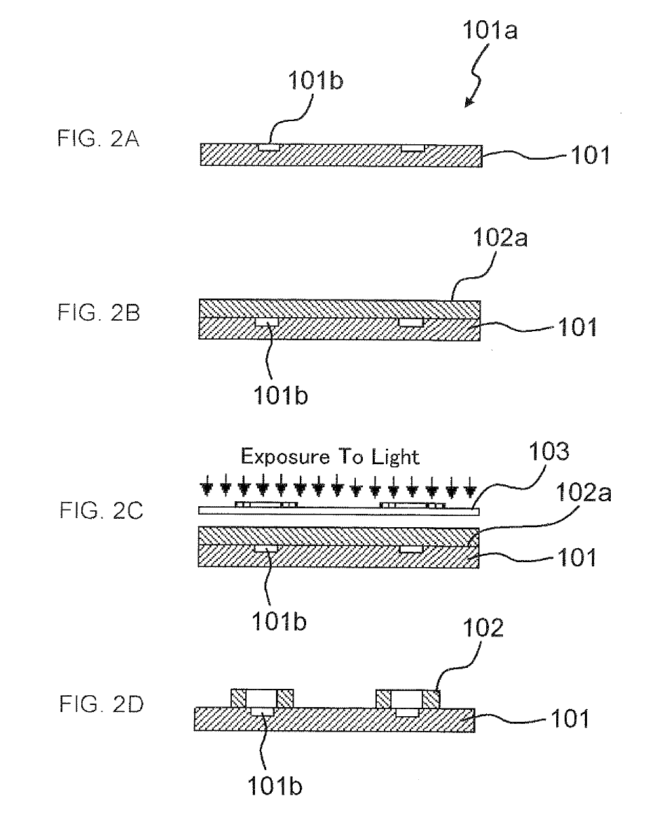

FIG. 1A is a perspective view, illustrating an electronic device in first embodiment, and FIG. 1B is a cross-sectional view along line A-A′ in FIG. 1A. FIGS. 2A to 2D, 3A to 3C, 4A to 4C and 5A to 5C are cross-sectional views, illustrating a process for manufacturing an electronic device in first embodiment.

An electronic device 108 includes: a photo-sensitive element 101 formed in a wafer 101a; an optically-transparent layer 113 formed on a functional unit 101b of the photo-sensitive element 101; a frame member 102 installed to surround the functional unit 101b and the optically-transparent layer 113 on the wafer 101a; and an encapsulating resin layer 106 filling a periphery of the frame member 102, where an upper surface of the frame member 102 is higher than the height of an upper surface of the encapsulating resin layer 106. The photo-sensitive element 101 is also electrically coupled to lead frames 104 through metallic thin lines 105.

The photo-sensitive element 101 having a plurality of functional units 101b is formed on the wafer 101a (FIG. 2A). The functional unit 101b is exposed over the surface of the photo-sensitive element 101. The functional unit 101b is capable of receiving light through the optically-transparent layer 113.

The frame member 102 has a hollow space, which interiorly surround the functional unit 101b and optically-transparent layer 113. A cross-section of the frame member 102 may be, for example, circular, and may alternatively be polygonal.

The frame member 102 is formed of a resin (first resin), which is completely curable with a light and/or a heat. More specifically, the frame member 102 is formed by patterning a resin film 102a, which is composed of the first resin in a form of a film.

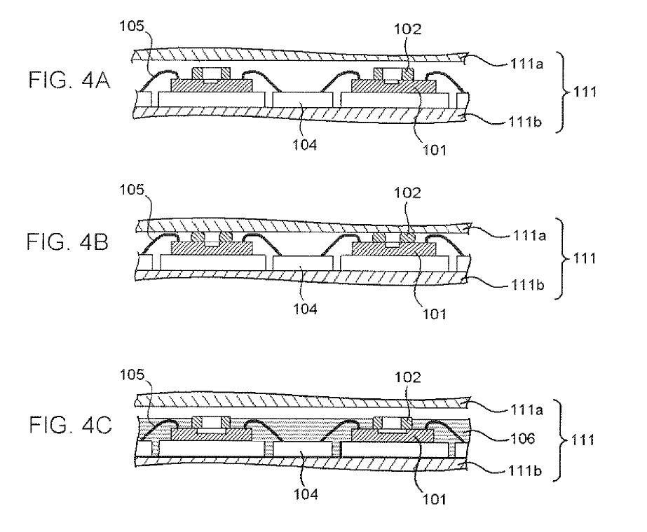

A height of the frame member 102 is 0.12 mm. The height of the frame member 102 may be preferably equal to or higher than 0.05 mm, and more preferably equal to or higher than 0.1 mm. Since the frame member 102 can be designed to have a height that is higher than the metallic thin line 105, unwanted contact of the metallic thin line 105 coupled to the lead frame 104 from a predetermined position of the photo-sensitive element 101 with the encapsulating metallic mold 111 employed in the manufacture process for the electronic device 108 can be avoided (see FIG. 4B). Therefore, a close contact of the encapsulating metallic mold 111a with the upper surface of the frame member 102 can be achieved, so that a penetration of a resin (second resin) for forming the encapsulating resin layer 106 over the surface of the frame member 102 can be prevented. The height of the frame member 102 is a length in the vertical direction from a principal surface of the wafer 101a to an upper surface of the frame member 102, and is also equivalent to a thickness of the resin composing the frame member 102.

The elastic modulus of the frame member 102 is preferably equal to or higher than 1 GPa and equal to or lower than 6 GPa at 20 degrees C., and equal to or higher than 10 MPa and equal to or lower than 3 GPa at 200 degrees C. The elastic modulus of within a range of from 1 GPa to 6 GPa at 20 degrees C. provides a function for protecting the photo-sensitive element 101 of the electronic device 108. On the other hand, the elastic modulus of within a range of from 10 MPa to 3 GPa at 200 degrees C. provides a protection of the the photo-sensitive element 101 to the applied pressure, since the frame member 102 can exhibit a smaller amount of elastic deformation to function as a buffer material during the pressure contact with the encapsulating metallic mold 111 in manufacture process for the electronic device 108. The elastic modulus of the frame member 102 is an elastic modulus of the resin composing the frame member 102 in the condition that the resin is completely cured with a light and a heat.

The frame member 102 has the upper surface that is not lower than the upper surface of the encapsulating resin layer 106, and is configured to project upwardly from the encapsulating resin layer 106. The height of the upper surface of the frame member 102 is equal to or larger than 0 mm and equal to or lower than 0.06 mm from the height of the upper surface of the encapsulating resin layer 106.

The encapsulating resin layer 106 is formed of a resin for encapsulation (second resin). The encapsulating resin may contain an inorganic filler, and more specifically a glass filler. This provides enhanced strength of the encapsulating resin layer 106.

The optically-transparent layer 113 is installed so as to cover the functional unit 101b located in the inside of the frame member 102 on the photo-sensitive element 101. The upper surface of the optically-transparent layer 113 is higher than the upper surface of the frame member 102, and is a convex surface. More specifically, the surfaces of the optically-transparent layer 113 exposed to the outside of the frame member 102 are curved.

The optically-transparent layer 113 is formed of a resin (third resin), which is completely curable with a light and/or a heat. It is composed of an optically-transparent material.

A process for manufacturing an electronic device in first embodiment will be described in reference to FIGS. 2A to 2D, 3A to 3C, 4A to 4C and 5A to 5C. FIGS. 2A to 2D, 3A to 3C, 4A to 4C and 5A to 5C are cross-sectional views, illustrating a process for manufacturing an electronic device in first embodiment.

A process for manufacturing the electronic device 108 includes: forming the resin film 102a composed of the first resin over the wafer 101a having a plurality of photo-sensitive elements 101 formed therein; patterning the resin film 102a to form the frame member 102 installed to surround the functional unit 101b of the photo-sensitive element 101; forming a resin layer 106, which fills a periphery of the frame member 102, by injecting the second resin into a cavity of an encapsulating metallic mold 111 while a molding surface of the encapsulating metallic mold 111 is in contact with an upper surface of the frame member 102; and after the operation for forming the resin layer, forming an optically-transparent layer 113 in a space in the inside of the frame member 102.

First of all, as shown in FIG. 2A, the wafer 101a having a plurality of photo-sensitive elements 101 formed therein is prepared. The functional units 101b are exposed on the surface of the respective photo-sensitive elements 101 disposed in the wafer 101a. In the illustration of FIG. 2A, only two of the photo-sensitive elements 101 disposed in the wafer 101a are shown.

Next, as shown in FIG. 23, the resin film 102a (first resin) is formed on the wafer 101a. A film having a uniform thickness serving as the resin film 102a covers the entire wafer 101a. The thickness of the resin film 102a is 0.12 mm. The frame member 102 having a height of 0.12 mm is thus obtained.

Subsequently, as shown in FIG. 20, an exposure process is conducted while an alignment is achieved so that the functional unit 101b is fitted into a predetermined position formed in the upper surface of the exposure mask 103, and the resin film 102a is patterned so as to form a frame member 102 installed to surround the functional unit 101b.

Further, as shown in FIG. 2D, a development processing is conducted to remove the portions of the resin film 102a except for the frame member 102. As described above, the photolithography method is employed to form the frame member 102 so as to be installed to cover the periphery of the functional unit 101b.

In addition to above, since the resin film 102a (first resin) for forming the frame member 102 is not completely cured at the time after the development processing, the frame member 102 and the Wafer 101a, or namely the frame member 102 and the photo-sensitive element 101, are adhered with a weak joining force, and not firmly adhered.

Subsequently, as shown in FIG. 2D, the wafer 101a having the frame member 102 formed therein is thermally processed to completely cure the resin film 102a (first resin), so that the frame member 102 and the Wafer 101a, or namely the frame member 102 and the photo-sensitive element 101, are firmly adhered. Substantially no geometrical change of the frame member 102 is caused by such thermal processing, the feature of the frame member 102 is substantially the same as the feature of the frame member 102 shown in FIG. 2D.

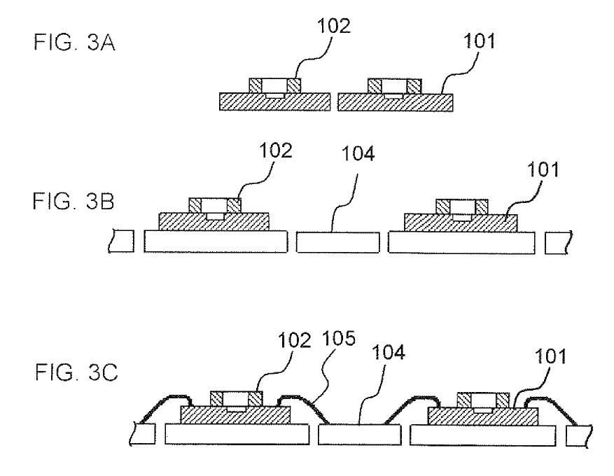

Then, as shown in FIG. 3A, the wafer 101a is diced into the individual photo-sensitive elements 101 to obtain the photo-sensitive element 101 having the frame member 102. The frame member 102 is formed to be cylindrical.

In the present embodiment, the frame member 102 is adjusted to have the elastic modulus of about 2.4 GPa at an ambient temperature and of about 15 MPa at 200 degrees C. The elastic modulus of the frame member 102 may be suitably adjusted by suitably selecting the type of the resin curable with a light and a heat, the change in the content ratio of the ingredients such as the curing agent, or the manufacturing conditions such as intensity of the curing light, a curing temperature and the like.

Then, as shown in FIG. 3B, the photo-sensitive element 101 is adhered to a predetermined position on the lead frame 104 via an adhesive agent. Subsequently, as shown in FIG. 3C, the respective predetermined positions of the photo-sensitive element 101 and the lead frame 104 are electrically coupled through the metallic thin line 105. In addition to above, the photo-sensitive elements 101 are disposed on the lead frame 104 with a dense arrangement with a predetermined distance.

Next, the encapsulating operation for covering the photo-sensitive element 101, the metallic thin line 105 and the entire lead frame 104 around the frame member 102 with an encapsulating resin will be described hereinafter in reference to FIGS. 4A to 4C.

As shown in FIG. 4A, an encapsulating metallic mold segments 111a and 111b, each having a molding surface of a flat surface, are prepared, and the photo-sensitive elements 101 on the lead frame 104 as shown in FIG. 3C are fixed to predetermined positions of the encapsulating metallic mold segments 111a and 111b.

Subsequently, as shown in FIG. 4B, the upper surface of the frame member 102 is pressed against the molding surface of the encapsulating metallic mold segment 111a, and the molding surface of the encapsulating metallic mold segment 111b is also pressed against the lower surface of the lead frame 104. More specifically, a gap between the upper surface of the frame member 102 and the molding surface of the encapsulating metallic mold segment 111a and a gap between the lower surface of the lead frame 104 and the molding surface of the encapsulating metallic mold segment 111b are minimized, and the close contacts of the both are achieved.

Then, as shown in FIG. 4B, an encapsulating resin (second resin) melted by a heat is injected into a cavity surrounded by the respective molding surfaces of the encapsulating metallic mold segments 111a and 111b while the pressed condition with the encapsulating metallic mold segment 111 is maintained to form the encapsulating resin layer 106 that fills the periphery of the frame member 102.

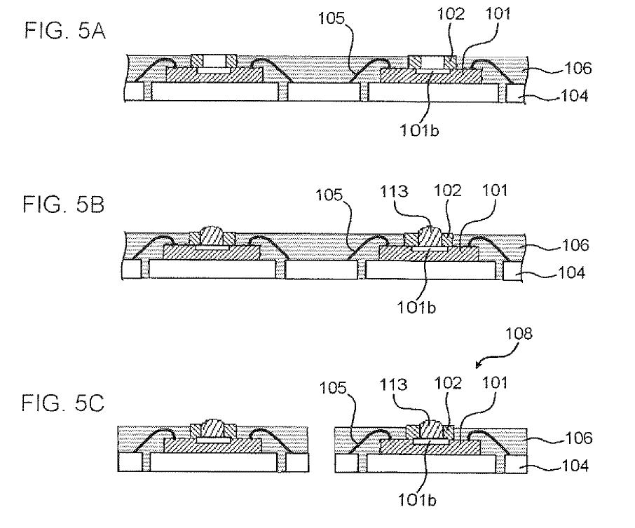

Then, as shown in FIG. 4C, the encapsulating metallic mold segments 111a and 111b are disassembled to obtain the photo-sensitive elements 101 formed to have the upper surfaces of the frame members 102 that are protruded to be slightly higher than the upper surface of the encapsulating resin layer 106. This allows that plurality of photo-sensitive elements 101 on the top of the lead frame 104 are totally encapsulated as shown in FIG. 5A.

Subsequently, as shown in FIG. 5B, an optically-transparent resin is injected over the functional units 101b of the photo-sensitive elements 101 that are exposed in the inside of the frame member 102 to form the optically-transparent layer 113 over the functional units 101b. Such optically-transparent resin is an optically-transparent liquid resin, and is also a resin that is curable with a light and a heat.

The formation of the optically-transparent layer 113 is achieved by injecting the optically-transparent resin with a dispenser and then curing the resin with a light or a heat, or a combination of a light and a heat. Since the frame member 102 is formed via a photolithographic process to have a precise feature, and since the constant quantity of the optically-transparent resin can be injected with the dispenser, the uniform formation of the optically-transparent layer 113 can be achieved. Further, in the present embodiment, the optically-transparent layer 113 is composed of a single layer.

The upper surface of the optically-transparent layer 113 is a convex surface, higher than the upper surface of the frame member 102, and has a feature of upwardly protruding from the frame member 102. Since the optically-transparent layer 113 is in liquid form, a surface tension may be utilized to provide a curved surface for the externally exposed surface. Such feature of the curved surface can be provided to be a desired curvature by changing the compounding ratio of a solvent over the optically-transparent layer 113 to change the viscosity.

Subsequently, as shown in FIG. 5C, the wafer is diced into the respective photo-sensitive elements 101 to obtain the electronic devices 108 having desired feature. The electronic device 108 means a device having one of, or both of a passive device and an active device formed in a surface of a semiconductor substrate or a glass substrate.

In the next, advantageous effects of the present embodiment will be described.

In the process for manufacturing the electronic device 108, the frame member 102 installed to surround the functional unit 101b and the optically-transparent layer 113 is formed on the wafer 101a, and then the resin layer 106, which fills the periphery of the frame member 102, is formed by injecting the encapsulating resin into the cavity of the encapsulating metallic mold 111 while the molding surface of the encapsulating metallic mold segment 111a is in contact with the upper surface of the frame member 102, and after the operation for forming the resin layer, the optically-transparent layer 113 is formed in the space in the inside of the frame member 102.

The encapsulating resin layer 106 is formed by injecting the encapsulating resin while the frame member 102 is in contact with the molding surface of the encapsulating metallic mold segment 111a. Therefore, a pressure applied in the encapsulation with the encapsulating metallic mold 111 is exerted over the frame member 102 around the functional unit 101b. Further, the optically-transparent layer 113 is formed after the encapsulation. Therefore, a transfer of the pressure applied in the encapsulation to the functional unit 101b caused by the contact of the encapsulating metallic mold segment 111a with the optically-transparent layer 113 can be avoided. This allows reducing the pressure applied in the encapsulation caused by the contact of the encapsulating metallic mold segment 111a with the functional unit 101b. Therefore, a generation of a crack in the functional unit 101b of the semiconductor element 101a can be reduced.

The molding surface of the encapsulating metallic mold segment 111a is in contact with the upper surface of the frame member 102 in the encapsulating process. This configuration prevents a flow of the encapsulating resin in the inside of the frame member 102 during the encapsulating process, so that the optically-transparent layer 113 can be formed on the inner side of of the frame member 102 after the encapsulating process.

In a process for manufacturing of electronic device 108, the molding surface of the encapsulating metallic mold segment 111a is firmly stuck with the upper surface of the frame member 102 by an external force generated by a clamping pressure, and the photo-sensitive element 101 is strongly adhered to the frame member 102. In such case, the elastic modulus of the frame member 102 is equal to or higher than 1 GPa and equal to or lower than 6 GPa at 20 degrees C., and equal to or higher than 10 MPa and equal to or lower than 3 GPa at 200 degrees C., so that the frame member 102 itself causes an elastic deformation by a clamping pressure of the encapsulating metallic mold 111 (see FIG. 45), and the external force generated by such clamping pressure may be absorbed to provide a protection for the photo-sensitive elements 101.

The elastic deformation of the frame member 102 may also cause an opposing force, which causes the frame member 102 closely contacting with the encapsulating metallic mold segment 111a. This prevents the encapsulating resin from flowing to the adhesion surface between the frame member 102 and the encapsulating metallic mold segment 111a.

In addition to above, the clamping pressure by the encapsulating metallic mold 11 may be caused by the encapsulating metallic mold segment 111a or by the encapsulating metallic mold segment 111b. The electronic device 108 can protect the functional unit 101b from the pressures caused by either of the encapsulating metallic mold segment 111a or the encapsulating metallic mold segment 111b, by the contact of the frame member 102 with the encapsulating metallic mold segment 111a.

The electronic device 108 in the present embodiment includes, as shown in FIG. 5A, a frame member 102 installed to surround the functional unit 101b and the optically-transparent layer 113 on the wafer 101a, and the upper surface of the frame member 102 is higher than the height of the upper surface of the encapsulating resin layer 106. The upper surface of the frame member 102 is higher than the height of the upper surface of the encapsulating resin layer 106. More specifically, the upper surface of the frame member 102 is higher than the upper surface of the encapsulating resin layer 106 by a distance within a range of from 10 micrometers to 60 micrometers.

This allows utilizing the elastic deformation of the frame member 102, thereby enhancing the adhesive force of of the frame member 102 with the encapsulating metallic mold segment 111a.

Further, in the design that the upper surface of the frame member 102 is higher than the upper surface of the encapsulating resin layer 106 by 0.06 mm or larger, an external force by a clamping pressure of the encapsulating metallic mold segment 111a may be increased, so that the deformation of the frame member 102 may become to be a plastic deformation, possibly causing a break.

On the other hand, when the upper surface of the frame member 102 is lower than the upper surface of the encapsulating resin layer 106, or namely when the height of the upper surface of the frame member 102 is lower than (lower than 0 mm) the height of the upper surface of the encapsulating resin layer 106, a problem of flowing the encapsulating resin to the surface of the frame member 102 (closely-contacted surface between the first resin film 102a and the encapsulating metallic mold segment 111a) and to the inside thereof may be caused.

Further, the reason for selecting the height of the upper surface of the frame member 102 to be not lower than the height of the upper surface of the encapsulating resin layer 106 is to avoid a flow of the encapsulating resin layer 106 into the surface of the frame member 102, even if the variation in the height of the frame member 102 is considered. The detail will be described below.

A variation in the height of the frame member 102 in the process for manufacturing the electronic device is about 10 micrometer by the standard deviation. The variation in the height of the frame member 102 is defined as a difference in the height of the frame member 102 that can be occurred in the operation for forming the frame member 102 when the film composed of the resin film 102a having a uniform thickness is formed via a photolithographic process, due to the process conditions such as quantity of light in the exposure process, the type of the liquid developer in the development process, a change in the disposition time and the like. It is desired to design the height of the frame member 102 to be the same as, or higher than the encapsulating resin layer 106 even if it would be the lowest height, in consideration of the variation occurred in the manufacturing process.

Thus, the height of the frame member 102 is designed to be higher than the upper surface of the encapsulating resin layer 106 by about 30 micrometer, which is three times of the standard deviation for the variation of such height. The design of the height of the frame member 102 may be suitably adjusted by adjusting a pressure for pressing the frame member 102 in the encapsulating process or the like (see FIG. 5A).

The height of the upper surface of the frame member 102 may be designed to be higher than the height of the upper surface of the encapsulating resin layer 106 by equal to or larger than 0 mm and equal to or lower than 0.06 mm. The elastic deformation of the frame member 102 provides an enhanced contact of the encapsulating metallic mold segment 111a.

Further, in the present embodiment, the resin film 102a in the film-like form may be employed to achieve forming the resin film 102a having an uniform thickness of 0.05 mm or thicker.

The reason is that the use of a fluid resin leads to a use of a low viscosity resin in order to provide a uniform film thickness over the entire wafer 101a, and such low viscosity of the resin may cause difficulty in obtaining the thickness of 0.05 mm. On the other hand, when a film having a thickness of equal to or higher than 0.05 mm is to be formed over the entire wafer 101a with a fluid resin, a high viscosity resin should be employed, such that the viscous resistance for coating over the wafer 101a is increased due to the high viscosity of the resin, leading to an increased variation in the film thickness to cause a difficulty in obtaining an uniform thickness.

The upper surface of the optically-transparent layer 113 is convex, so that the optically-transparent layer exhibits a lens effect, providing an improved condensing capability. The resin for forming the optically-transparent layer 113 (third resin) has an adhesive function, so that the resin can be directly installed on the functional unit 101b of the photo-sensitive element 101, and thus deteriorations of the device performances such as an optical refraction or an optical attenuation of the installed surface can be reduced. Further, since the optically-transparent layer 113 is composed of a single layer, deteriorations of the device performances such as an optical refraction or an optical attenuation of the installed surface can be reduced.

The adoption of the optically-transparent layer 113 only on the functional unit 101b avoids a necessity for employing a transparent resin for the encapsulating resin layer 106. This allows adding a reinforcing agent such as a glass filler and the like in the encapsulating resin layer 106.

Further, since a reinforcing agent having a lower thermal expansion is contained in the encapsulating resin layer 106 that covers the greater part of the electronic device 108, the encapsulating resin layer exhibits smaller thermal expansion as compared with the conventional optically-transparent encapsulating resin, so that the thermal expansion in the reflow operation for the encapsulating resin layer 106 can be controlled. More specifically, a warpage of the encapsulating resin layer 106 can be reduced to achieve a manufacturing of the photo-sensitive elements 101 on the lead frame 104 with a dense arrangement, so that the utility factor of the lead frame 104 is improved, and further, the waste area is decreased to allow a reduction of the wastes and a decrease in the manufacture cost. This allows providing an improved coupling reliability in the reflow operation.

In addition, an adherence auxiliary agent for improving the adhesiveness with the lead frame 104 may be added to the encapsulating resin layer 106 to prevent an incoming of water into an interface of the lead frame 104 and the encapsulating resin layer 106.

The conventional optically-transparent encapsulating resin changes its color by a heat in the reflow operation to lose its optical transparency when an adherence auxiliary agent is contained, and thus it is difficult to add the additional agent. However according to the electronic device 108 in the present embodiment, the dimensional change of the electronic device 108 is reduced and an amount of water incoming into the electronic device 108 is reduced, even if a sudden temperature-rise in the reflow process is caused, and therefore a vapor explosion in the electronic device 108 can be avoided. Therefore, the electronic device 108 having higher coupling reliability in the packaging of the electronic device 108 can be achieved.

Since the resin film 102a has a film-like shape and also has an adhesive function, the resin film may be formed on the wafer 101a all at once without dividing the wafer 101a, so that the frame member 102 having higher geometric accuracy can be produced with higher efficiency.

Furthermore, since the optically-transparent layer 113 can be formed by injecting the liquid third resin in the inside of the frame member 102 formed with higher accuracy, enhanced production efficiency can be achieved without a need for employing complicated facilities. More specifically, a need for employing highly precise parts or sophisticated facilities, as in the conventional examples, such as an installation of the individually formed parts for optical transmission with higher accuracy, or the like, can be avoided, and the processing all at once can also be achieved.

### Second Embodiment

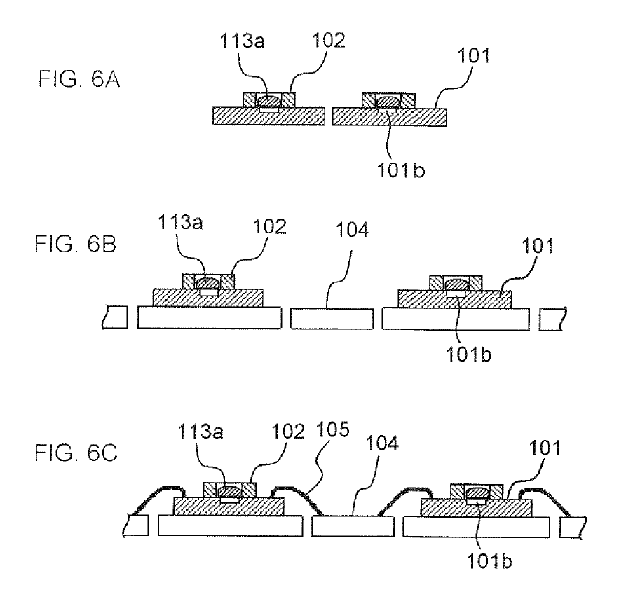

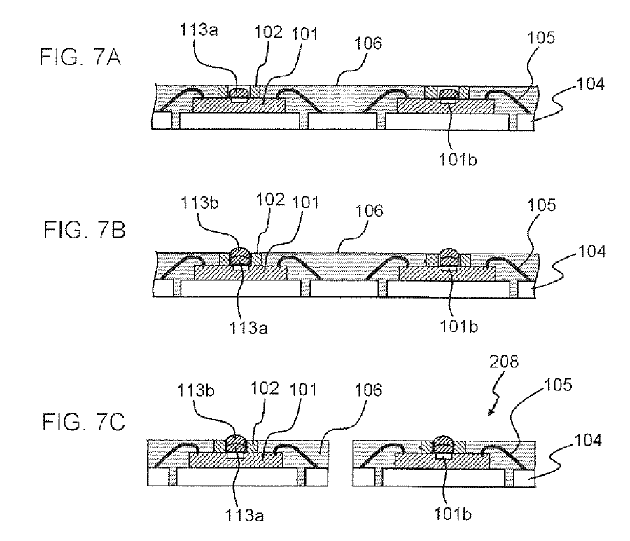

FIGS. 6A to 6C and FIGS. 7A to 7C are cross-sectional views, showing a process for manufacturing an electronic device in second embodiment. A process for manufacturing an electronic device in second embodiment is configured that, while the optically-transparent layer 113 of first embodiment is formed in the space inside of the frame member 102 after the encapsulating operation, an optically-transparent layer 113 of the present embodiment is formed to be lower than the upper surface of frame member 102 before the encapsulating operation, and further, an optically-transparent layer 113b is formed after the encapsulating operation. Other operations in the manufacturing process are similar to that in first embodiment.

The optically-transparent layer 113 in second embodiment is formed by a manufacturing process illustrated in FIGS. 6A to 6C. Other operations in the manufacturing process are similar to that in first embodiment, and thus the descriptions thereof are not presented.

First of all, the optically-transparent layer 113a disposed to be lower than the upper surface of the frame member 102 is formed in a space inside of the frame member 102 as shown in FIG. 6A, which has been formed as illustrated in FIG. 2A to FIG. 3A. The formation of the optically-transparent layer 113a is achieved by injecting an optically-transparent resin (third resin) with a dispenser and then curing the resin with a light or a heat, or a combination of a light and a heat.

Next, a wafer 101a is diced (FIG. 6A), and the diced chip is die-bonded on a lead frame 104 (FIG. 6B), and then a wire bonding is carried out (FIG. 6C). Further, a resin seal is formed similarly as shown in FIG. 4 to form an encapsulating resin layer 106 as shown in FIG. 7A.

In next, as shown in FIG. 7B, the optically-transparent layer 113b is formed on the optically-transparent layer 113a formed in the inside of the frame member 102. The optically-transparent layer 113b is formed of the resin, which is also employed for the optically-transparent layer 113a, by injecting the resin with a dispenser or the like to a position that is not lower than the height of the frame member 102. Then, the resin is cured with a light or a heat, or a combination of a light and a heat.

Subsequently, as shown in FIG. 70, the device is diced into the respective photo-sensitive elements 101 to obtain the electronic devices 208 having desired feature.

Advantageous effects of second embodiment will be described. Since the optically-transparent layer 113a is formed in the condition before dicing the wafer 101a, contamination of the functional unit 101b with dusts or contaminants can be prevented in the operation after the formation of the optically-transparent layer such as dicing of the wafer 101a, die bonding, wire bonding, resin seal and the like.

Further, even if dusts or contaminants are entered on the optically-transparent layer 113a, the presence of the optically-transparent layer 113a formed therein reduces a generation of a scratch in the functional unit 101b, and it is easy to remove dusts or contaminants by blowing or cleaning. Thus, the configuration is effective for improving the yield of the electronic device 208.

Further, the height of the optically-transparent layer 113a is selected to be lower than the height of the frame member 102, so that the frame member 102 itself causes an elastic deformation by a clamping pressure of the encapsulating metallic mold 111 in the resin seal operation, and the effect for absorbing the external force generated by such clamping pressure may be maintained to provide a protection for the photo-sensitive elements 101b. Further, since the optically-transparent layer 113 is lower than the upper surface of the frame member 102, a transfer of the pressure applied in the encapsulation to the functional unit 101b through the optically-transparent layer 113 can be avoided.

Other advantageous effects of the present embodiment are similar as in the above-described embodiment.

### Third Embodiment

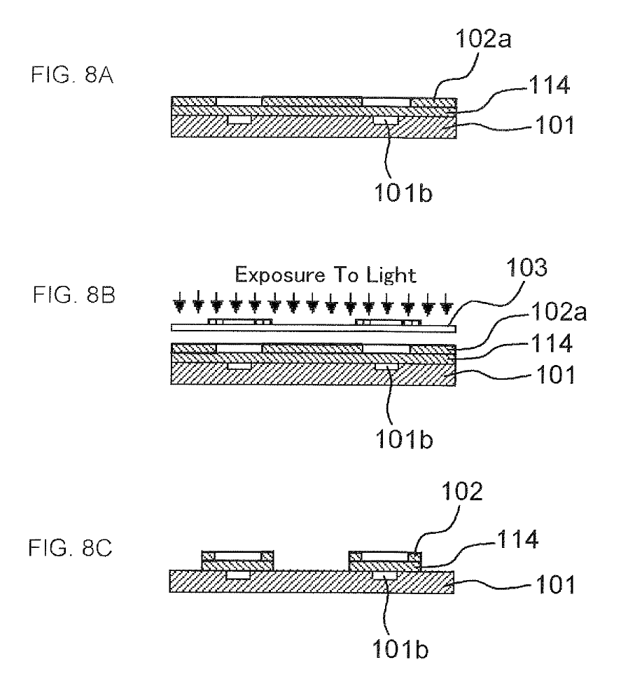

FIGS. 8A to 8C, FIGS. 9A to 9C and FIGS. 10A to 10C are cross-sectional views, showing a process for manufacturing an electronic device in third embodiment. A configuration of an electronic device in third embodiment is that, while the frame member 102 is formed on the surface of the wafer 101a in the above-described embodiments, an optically-transparent film 114 is formed between the wafer 101a and the frame member 102 and the optically-transparent layer 113 is deposited on the optically-transparent film 114 in the configuration of electronic device in the present embodiment. More specifically, the optically-transparent 114 located under, and in the inside of the frame member 102, and provided on wafer the 101a, are provided, and the optically-transparent layer 113 is deposited on the optically-transparent film 114.

A configuration of third embodiment, in which the optically-transparent film 114 is formed between the wafer 101a and the frame member 102 and the optically-transparent layer 113 is deposited on the optically-transparent film 114, is formed by a manufacturing process shown in FIGS. 8A to 8C. Other operations in the manufacturing process are similar to that in first embodiment, and thus the descriptions thereof are not presented.

As shown in FIG. 8A, the optically-transparent film 114 is formed on the wafer 101a. The optically-transparent film 114 is composed of a film-formed material of an optically-transparent resin (third resin). Successively, the resin film 102a having an opening in a position, where the functional unit 101b is formed, is formed on the optically-transparent film 114. The optically-transparent layer 114 is formed of the resin, which is also employed for the optically-transparent layer 113a

As shown in FIG. 8B, an exposure process is conducted while an alignment is achieved so that the functional unit 101b is fitted into a predetermined position formed in the upper surface of the exposure mask 103, and the resin film 102a is patterned so as to form a frame member 102 installed to surround the functional unit 101b.

Further, as shown in FIG. 8C, the resin film 102a and the optically-transparent film 114 except the frame member 102 are removed to form the frame member 102 so as to be installed to cover the periphery of the functional unit 101b. In other words, the optically-transparent film 114 is formed between the wafer 101a and the frame member 102.

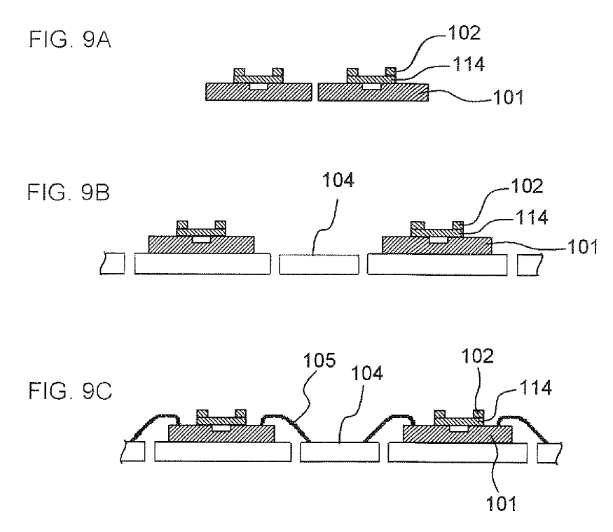

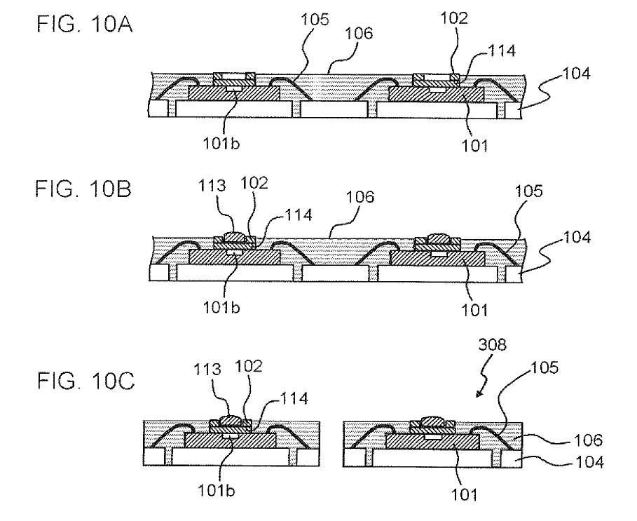

Next, the wafer 101a is diced into single pieces (FIG. 9A), and a die bonding is achieved on the lead frame 104 (FIG. 9B) to achieve a wire bonding (FIG. 9C). Further, a resin seal is formed similarly as shown in FIG. 4 to form an encapsulating resin layer 106 as shown in FIG. 10A.

Subsequently, as shown in FIG. 10B, an optically-transparent resin is injected over the functional units 101b of the photo-sensitive elements 101 disposed in the inside of the frame member 102 to form the optically-transparent layer 113 in the space in the inside of the functional units 101b. Such optically-transparent resin is an optically-transparent liquid resin, and is also a resin that is curable with a light and a heat.

Subsequently, as shown in FIG. 10C, the device is diced into the respective photo-sensitive elements 101 to obtain the electronic devices 308 having desired feature.

Advantageous effects of third embodiment will be described. While second embodiment includes two operations for injecting the resin into the interior of the frame member 102 to form the optically-transparent layer 113a and the optically-transparent layer 113b, a single operation is sufficient for achieving such operation for injecting resin in third embodiment, so that a reduction in the manufacturing operations can be achieved, leading to further improved production efficiency.

In addition, the same material is employed for the optically-transparent layer 113 and the optically-transparent film 114, so that a boundary surface overlapping the optically-transparent layer and the optically-transparent film disappears by a fusion integration occurred when the optically-transparent layer 113a is formed, achieving reduced optical refraction and attenuation.

The optically-transparent film 114 is designed to have an elastic modulus of about 2.4 GPa at a room temperature, and of about 15 MPa at a temperature of 200 degrees C. This allows relaxing a stress in the encapsulation.

Other advantageous effects of the present embodiment are similar as in the above-described embodiment.

The electronic device and the process for manufacturing thereof according to the present invention are not limited to the above-described embodiments, and various modifications are also available.

For example, the operation for forming the resin film 102a on the wafer 101a having a plurality of elements formed therein may includes forming the resin film 102a by overlaying a plurality of film-form resin sheets. This allows providing larger height of the frame member 102 or suitably adjusting at a preferable height.

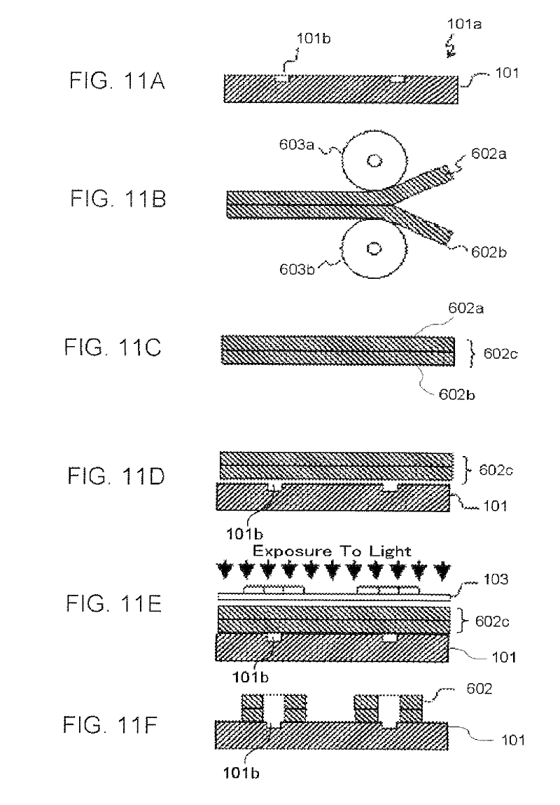

Here, a method for suitably adjusting the height of the frame member 102 will be described in reference to FIGS. 11A to 11F. FIGS. 11A to 11F are cross-sectional views, illustrating an operation for forming the frame member 102 to be in the present embodiment thick.

First of all, as shown in FIG. 11A, the wafer 101a having a plurality of photo-sensitive elements 101 formed therein is prepared. The functional units 101b are formed in the surface of the respective photo-sensitive elements 101 disposed in the wafer 101a. In the illustration of FIG. 11A, only two of the photo-sensitive elements 101 disposed in the wafer 101a are shown.

Next, as shown in FIG. 11B, film-formed resin films 602a and 602b having a thickness of 0.065 mm, composed of a resin that is curable with a light or a heat, or a combination of a light and a heat, are prepared.

Subsequently, as shown in FIG. 11C, the resin films 602a and 602b are overlaid through rolls 603a and 603b with a certain compression via a roll laminator process to obtain a resin film 602c exhibiting substantially no “warp” or “wrinkle”. In addition, since the films having uniform thickness are employed for the resin films 602a and 602b, the resin film 602c formed by overlaying the resin films 602a and 602b also has a uniform thickness.

Next, as shown in FIG. 11D, the resin film 602c is disposed on the wafer 101a via a vacuum laminator process substantially without a generation of bubbles in the contact surface between the resin film 602c and the wafer 101a to cover the entire wafer 101a with the resin film 602c. The thickness of the resin film 602c is 0.13 mm.

Subsequently, as shown in FIG. 11E, an exposure is carried out to pattern the resin film 602c for forming the frame member 102, thereby obtaining the frame member 102 (FIG. 11F). The operations thereafter are similar to that in first embodiment.

Results of trial manufactures show that the frame member 102 may be formed via a photolithographic process even if the resin film 602c is composed of the resin films 602a and 602b.

In addition, at least a sheet of a plurality of film-form resin sheets may have optical transparency. More specifically, any one of the resin films 602a and 602b may be a film-formed material of an optically-transparent resin. For example, the film-formed optically-transparent film 114 as described in the above-described embodiment may be employed to be adhered with either the resin film 602a or the resin film 602b. However, when the resin films 602a and 602b are not optically-transparent, the side of the optically-transparent film 114 is adhered with the wafer 101a, and the resin film 602a or 602b is employed to form the frame member 102.

Dual layered film-formed resin sheets composed of the resin films 602a and 602b are employed to achieve the film thickness of the resin film 602c of not smaller than 0.08 mm. In other words, larger height of the frame member 102 can be achieved.

In the meantime, the solvent employed for forming the resin films 602a and 602b is required to be removed for providing the film-form. The thickness of the resin sheet of larger than 0.08 mm causes a difficulty in removing the solvent. In other words, it is difficult to remove the solvent from the processed material such as a film. The use of two of the overlaid films of equal to or smaller than 0.08 mm, which exhibits easier removal of the solvent therefrom and better processibility, allows an increased film thickness of the resin film 602c.

In the meantime, when the resin films 602a and 602b are sequentially formed on the wafer 101a, a “warp” and a “wrinkle” may be occurred in the resin films 602a and 602b, when the first sheet, for example the resin film 602a, is formed on the wafer 101a and then the second sheet of the resin film 602b is formed thereon. On the contrary, the previously overlaid dual-layered resin films 602a and 602b is employed before forming the resin film 102a on the wafer 101a to reduce a “warp” and a “wrinkle” occurred due to an adhesiveness of the resin films 602a and 602b.

In addition, the above-mentioned roll laminator process may be employed for overlaying the resin films 602a and 602b. The use of the roll laminator process causes the resin films 602a and 602b mutually contacting with a pressure in limited sections in the resin films to allow a “warp” and/or a “wrinkle” in the films escaping to the non-pressure-contacted sections even if the resin films exhibit mutual adhesiveness, resulting in overlaying the resin films substantially without a “warp” or a “wrinkle”.

In addition, the process for forming the resin film 602c overlaid on the wafer may alternatively employ a vacuum laminator process. More specifically, the use of the vacuum laminator process allows easier removal of bubbles generated between the wafer 101a and the resin film 602c and a uniform pressurizing over the entire wafer 101a even if thinner wafer 101a is employed, thereby preventing a generation of a crack in the wafer 101a.

The frame member 102 has larger height and larger distances of a top of the metallic thin line 105 with the encapsulating metallic mold segments 111a and 111b, such that unwanted contact of the metallic thin line 105 can be avoided with a larger margin (see FIG. 4B). In addition, the increased height of the frame member 102 allows enhanced flexibility of design for the heights of the encapsulating resin layer 106 and the frame member 102.

As described in first embodiment, the frame member 102 may be designed to have the height, which is higher by up to 0.06 mm than the height of the encapsulating resin layer 106. Furthermore, larger height of the frame member 102 from the encapsulating resin layer 106 provides larger elastic deformation to cause an opposing force, which lead to a stronger close contact between the frame member 102 and the encapsulating metallic mold segment 111a, thereby preventing a penetration of the encapsulating resin layer 106 into the upper surface of the frame member 102. The increased height of the frame member 102 ensures sufficient thickness of the encapsulating resin layer 106 without exposing the photo-sensitive element 101 or the metallic thin line 105, so that the height of the frame member 102 from the encapsulating resin layer 106 can be increased up to 0.06 mm, while protecting the encapsulating resin.

Further, various modifications are also available for the electronic device and the process for manufacturing thereof according to the present invention. For example, in the encapsulating operation, a film 412 may further be disposed on the molding surface of the encapsulating metallic mold 111. The encapsulating operation in this case will be described below.

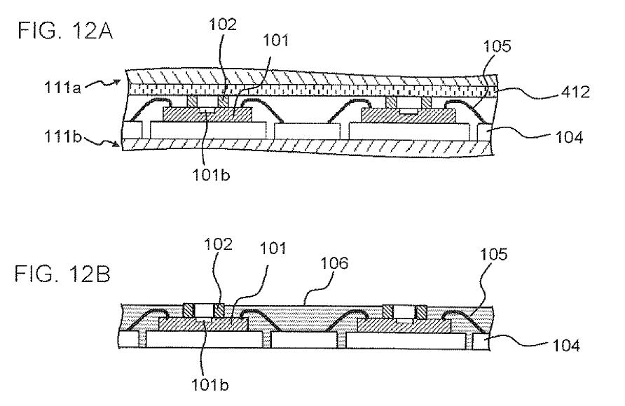

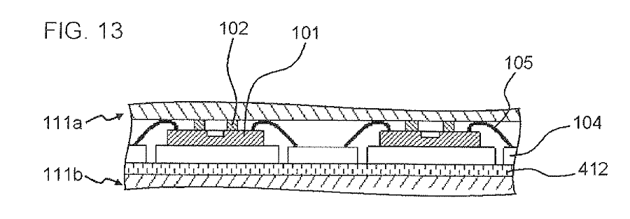

FIG. 12A, FIG. 12B and FIG. 13 are cross-sectional views, illustrating the encapsulating operation in a modified example of the present embodiment. As shown in FIG. 12A, encapsulating metallic mold segments 111a and 111b having flat surfaces serving as molding surfaces are prepared, and the upper surface of the frame member 102 is pressed against the molding surface of the encapsulating metallic mold segment 111a via the film 412 that is an elastic material, and the molding surface of the encapsulating metallic mold segment 111b is pressed against the lower surface of the lead frame 104. Subsequently, an encapsulating resin in thermally melted form is injected therein while the condition of the pressing is maintained to form the encapsulating resin layer 106 as shown in FIG. 12B.

Since the film 412 is an elastic material, such elasticity of the film causes an elastic deformation of the frame member 102 itself and an elastic deformation of the film 412. The film 412 may preferably be composed of a soft material such as, for example, a silicone material. This allows an elastic deformation of the frame member 102 itself and the film 412 by a clamping pressure caused by the encapsulating metallic mold, and an external force generated by such clamping pressure is absorbed to provide further protection of the functional unit 101b.

Further, such elastic deformation also causes an opposing force for pressing the frame member 102 and the film 412 against the encapsulating metallic mold segment 111a, so that further close contact between the frame member 102 and the film 412 can be achieved.

Further, since the frame member 102 is further pressed against the film 412 to create further close contact, flowing of the encapsulating resin in the inside of the frame member 102 can be avoided, even if the difference between the height of the upper surface of the frame member 102 and the upper surface of the encapsulating resin layer 6 is increased. Thus, an improved flexibility for the design of the frame member 102 can be achieved.

On the other hand, as shown in FIG. 13, the encapsulating metallic mold segments 111a and 111b having flat surfaces serving as molding surfaces may be prepared, and the upper surface of the frame member 102 is pressed against the molding surface of the encapsulating metallic mold segment 111a, and the molding surface of the encapsulating metallic mold segment 111b may be pressed against the lower surface of the lead frame 104 via the film 412 that is an elastic material.

Similarly as in the case of the above-described configuration, since the film 412 is an elastic material in the case shown in FIG. 13, such elasticity of the film causes an elastic deformation of the frame member 102 itself and an elastic deformation of the film 412. The film 412 may preferably be composed of a soft material such as, for example, a silicone material. This allows an elastic deformation of the frame member 102 itself and the film 412 by a clamping pressure caused by the encapsulating metallic mold, and an external force generated by such clamping pressure is absorbed to provide further protection of the functional unit 101b.

The film 412 may be inserted and fixed between encapsulating metallic mold segment 111b of FIG. 13 and lead frame 104 to avoid a formation of a gap between the lead frame 104 and the film 412, thereby preventing a penetration of the encapsulating resin into the surface of the lead frame facing the photo-sensitive element 101, or namely the surface having the electronic device 108 installed thereon.

In addition, the film 412 may be employed between the upper surface of the frame member 102 and molding surfaces of the encapsulating metallic mold segment 111a and/or between the molding surface of the encapsulating metallic mold segment 111b and the lead frame 104.

While the descriptions have been made in the above-described embodiment for the configurations, in which the height of the upper surface of the frame member 102 is higher than the upper surface of the encapsulating resin layer 106, a configuration, in which an upper surface of the frame member 102 is coplanar with an upper surface of the encapsulating resin layer 106, may be alternatively available. In this case, it is preferable to be in close contact between the frame member 102 and the encapsulating metallic mold 111, for the purpose of preventing the encapsulating resin from flowing in the inside of the frame member 102 in the encapsulating operation.

While the descriptions have been made in the above-described embodiment for the configurations, in which the shape of the frame member 102 is cylindrical, the shape of the frame member may alternatively be other type of tubular shape such as cylindroid, quadrangular prism and the like.

While the descriptions have been made in the above-described embodiment for the configurations, in which the cured material of the optically-transparent resin is employed for the optically-transparent layer 113, the optically-transparent layer may alternatively be formed by disposing a previously-cured optically-transparent member in the inner space of the frame member. For example, the optically-transparent layer 113 may be formed with a glass or an acrylic material.

It is apparent that the present invention is not limited to the above embodiment, and may be modified and changed without departing from the scope and spirit of the invention.

What is claimed is:

1. A process for manufacturing an electronic device, comprising:
forming a resin film composed of a first resin over a wafer having a plurality of elements formed therein;
patterning said resin film to form a frame member installed to surround a functional unit of said element; and
forming a resin layer by injecting a second resin into a cavity of an encapsulating metallic mold while a molding surface of said encapsulating metallic mold is in contact with an upper surface of said frame member, said resin layer filling a periphery of said frame member,
wherein said process includes, before or after said forming the resin layer, forming an optically-transparent layer in a space in the inside of said frame member.

2. The process for manufacturing the electronic device as set forth in claim 1, wherein an upper surface of said optically-transparent layer formed after said forming the resin layer is located to be higher than an upper surface of said frame member.

3. The process for manufacturing the electronic device as set forth in claim 1, wherein the first resin is a resin, which is curable with a light and/or a heat.

4. The process for manufacturing the electronic device as set forth in claim 1, wherein the second resin contains an inorganic filler.

5. The process for manufacturing the electronic device as set forth in claim 1, wherein said optically-transparent layer is formed by injecting an optically-transparent resin into a space in the inside of said frame member and curing the optically-transparent resin with a light and/or a heat.

6. The process for manufacturing the electronic device as set forth in claim 1, wherein said optically-transparent layer is formed by disposing a molded optically-transparent member into a space in the inside of said frame member.

7. The process for manufacturing the electronic device as set forth in claim 1, wherein said forming the resin film includes forming said resin film by overlaying a plurality of film-formed resin sheets.

8. The process for manufacturing the electronic device as set forth in claim 7, wherein at least one of said plurality of film-formed resin sheets has an optical transparency.

9. The process for manufacturing the electronic device as set forth in claim 7, wherein said resin film is formed by overlaying a plurality of film-formed resin sheets via a roll laminator process, and wherein said resin film is adhered over said wafer via a vacuum laminator process.

10. An electronic device, comprising:
an element formed in a wafer;
an optically-transparent layer formed over a functional unit of said element;
a frame member installed over said wafer to surround said functional unit and said optically-transparent layer; and
a resin layer filling a periphery of said frame member,
wherein an upper surface of said frame member is not lower than an upper surface of said resin layer.

11. The electronic device as set forth in claim 10, wherein an upper surface of said optically-transparent layer is higher than the upper surface of said frame member.

12. The electronic device as set forth in claim 10, wherein the upper surface of said optically-transparent layer is a convex surface.

13. The electronic device as set forth in claim 10, wherein an elastic modulus of said frame member is within a range of from 1 GPa to 6 GPa at 20 degrees C., and within a range of from 10 MPa to 3 GPa at 200 degrees C.

14. The electronic device as set forth in claim 10, wherein said frame member is a cured product of a resin, which is curable with a light and/or a heat.

15. The electronic device as set forth in claim 10, further comprising an optically-transparent film located under said frame member and in the inside thereof and provided on said wafer, wherein said optically-transparent layer is disposed on said optically-transparent film.

16. The electronic device as set forth in claim 10, wherein said optically-transparent layer is a cured product of a resin, which is curable with a light and/or a heat.

17. The electronic device as set forth in claim 10, wherein said optically-transparent layer is formed by employing a glass or an acrylic resin.

18. The electronic device as set forth in claim 10, wherein an upper surface of said frame member is higher by a distance within a range of from 0 mm to 0.06 mm than an upper surface of the resin layer.

19. The electronic device as set forth in claim 10, wherein a height from a surface of said wafer to the upper surface of said frame member is equal to or higher than 0.05 mm.

20. The electronic device as set forth in claim 10, wherein said frame member is formed of a film-formed resin sheet or a multi-layered member of said film-formed resin sheets.

21. The electronic device as set forth in claim 10, wherein said resin layer contains an inorganic filler.
